(19) United States
(12) Patent Application Publication
(10) Pub. No.: US 2019/0098790 A1
(43) Pub. Date: Mar. 28, 2019

(54) Angular Vertical Cable Manager

(71) Applicant: Hoffman Enclosures, Inc., Anoka, MN (US)

(72) Inventor: Brian L. Mordick, Shoreview, MN (US)

(21) Appl. No.: 16/140,206

(22) Filed: Sep. 24, 2018

Related U.S. Application Data
(60) Provisional application No. 62/561,860, filed on Sep. 22, 2017.

(51) Int. Cl. H05K 7/14

(52) U.S. Cl. CPC H05K 7/1491; H05K 5/0247

(57) ABSTRACT

A cable manager can include a base, a first arm, and a second arm. The first arm can extend from one side of the base at a first angle that is greater than about 90 degrees and less than about 180 degrees, and can be configured to be coupled to a first electronic equipment rack. The second arm can extend from another side of the base at a second angle that is greater than about 90 degrees and less than about 180 degrees, and can be configured to be coupled to a second electronic equipment rack.

### RELATED APPLICATIONS

This application claims priority under 35 U.S.C. § 119 to U.S. Provisional Patent Application No. 62/561,860 filed on Sep. 22, 2017, the entire contents of which is incorporated herein by reference.

### BACKGROUND

Cable managers are used to organize cables and wires linked to electrical equipment stored on equipment racks, frames, or cabinets. More specifically, cable managers can allow large numbers of wires or cables to enter and/or exit at specific locations along an equipment rack, frame, or cabinet in a direct and manageable manner. As a result, cable managers can allow for easy and quick installation, removal, and servicing of the electrical equipment. With numerous possible configurations of electrical equipment inside frames, racks, or cabinets, it would be desirable to provide a cable manager that incorporates versatile features for adapting to different configurations.

### SUMMARY

Some embodiments provide a cable manager configured to be coupled to at least one electronic equipment rack. The cable manager includes a base, a first arm, and a second arm. The first arm extends from one side of the base at a first angle that is greater than about 90 degrees and less than about 180 degrees, and is configured to be coupled to a first electronic equipment rack, lite second arm extends from another side of the base at a second angle that is greater than about 90 degrees and less than about 180 degrees, and is configured to be coupled to a second electronic equipment rack.

Other embodiments provide a cable management, system include an angular cable manager, a first electronic equipment rack, and a second electronic equipment rack. The angular cable manager includes a body with a base and a first arm and a second arm extending from either side of the base to partially define a conduit between the base, the first arm, and the second arm. The first electronic equipment rack is coupled to the first arm and the second electronic equipment rack is coupled to the second arm. The second electronic equipment rack is positioned relative to the first electronic equipment rack at an angle less than about 180 degrees.

### BRIEF DESCRIPTION OF THE DRAWINGS

The accompanying drawings, which are incorporated in and form, a part of this specification, illustrate embodiments of the invention and, together with the description, serve to explain the principles of embodiments of the invention:

FIG. 1 is an exploded isometric view of an angular vertical cable manager according to some embodiments of the invention;

FIGS. 2A, 2B, and 2C are top, front, and side views, respectively, of the cable manager of FIG. 1;

FIG. 3 is a top schematic view of a cable manager according to some embodiments;

FIG. 4 is a front view of a body of an adjustable angular cable manager according to some embodiments;

FIG. 5 is a top schematic view of an adjustable angular Vertical cable manager according to some embodiments, and FIG. 5A is a top schematic view of a door configuration for use with the adjustable cable manager of FIG. 5;

FIG. 6 is a front view of a body of the adjustable angular vertical cable manager of FIG. 5;

FIG. 7 is an isometric view of a finger array of the cable manager of FIG. 1;

FIG. 8 is a partial top-down isometric view of an upper portion of the cable manager of FIG. 1 with an end cap removed;

FIG. 9 is a partial top-down isometric view of a lower portion of the cable manager of FIG. 1;

FIG. 10 is a partial rear view of a door of the cable manager of FIG. 1, and FIG. 10A is an exploded partial rear view of the door of FIG. 10;

FIG. 11 is art isometric view of a cable manager, according, to some embodiments, coupled to two electrical equipment racks to form a cable management system having “L-shaped” configuration;

FIG. 12 is a top schematic view of a cable management system comprising two cable managers, according to some embodiments, coupled to three electrical equipment racks in a “U-shaped” configuration;

FIG. 13 is an isometric view of a cable management system comprising two cable managers, according to some embodiments, coupled to three electrical equipment racks in a “U-shaped” configuration;

FIG. 14 is a top schematic view of a cable management system comprising two cable managers, according to some embodiments, coupled to three electrical equipment racks in a “U-shaped” configuration, and two conventional cable managers coupled to free ends of the electrical equipment racks:

FIG. 15 is a top schematic view of a cable management system comprising two cable managers, according to some embodiments, coupled to three electrical equipment racks in an “S-shaped” configuration;

FIG. 16 is a top schematic view of a cable management system comprising three cable managers, according to some embodiments, coupled to four electrical equipment racks in a “W-shaped” configuration; and

FIG. 17 is an isometric view of a cable management system comprising three cable managers, according to some embodiments, coupled to four electrical equipment racks in a “W-shaped” configuration.

### DETAILED DESCRIPTION

Before any embodiments of the invention: are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use embodiments of the invention. Various modifications to the illustrated embodiments will be readily apparent to those skilled in the art, and the generic principles herein can be applied to, other embodiments and applications without departing from embodiments of the invention. Thus, embodiments of the invention are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

As used herein, unless otherwise specified or limited, “at least one of A, B, and C,” and similar other phrases, are meant to indicate A, or B, or C, or any combination of A, B, and/or C. As such, this phrase, and similar other phrases can include single or multiple instances of A, B, and/or C, and, in the case that any of A, B, and/or C indicates a category of elements, single or multiple instances of any of the elements of the categories A, B, and C.

As used herein, unless otherwise specified or limited, the term “L-shaped” specifies a shape that includes a first leg portion, with a second leg portion extending generally perpendicularly from the first leg portion. However, other angles may be contemplated while remaining in a substantially L-shaped configuration, such as any angle between about 45 degrees and about 135 degrees, or greater than or equal to about 45 degrees and less than about 180 degrees. In some embodiments, an “L-shaped” configuration can include a second leg portion extending from a first leg portion at a substantially right angle (or other angle) relative to the base portion, with or without curved or compound-angle connecting regions between the first leg portion and the second leg portion. In some embodiments, additional protrusions or contours that do not substantially alter the overall profile of the shape can extend from the first leg portion and/or second leg portion in an L-shaped configuration.

As used herein, unless otherwise specified or limited, the term “U-shaped” specifies a shape that includes a central portion, with at least two leg portions extending in generally similar directions from the central portion. In some embodiments, a “U-shaped” configuration can include leg portions extending from opposite ends of a central portion at substantially right angles to the central portion, with or without curved or compound-angle connecting regions between the leg portions and the central portion. However, other angles may be contemplated while remaining in a substantially U-shaped configuration, such as any angle between about 45 degrees and about 135 degrees, or greater than or equal to about 45 degrees and less than about 180 degrees. In some embodiments, additional protrusions or contours that do not substantially alter the overall profile of the shape can extend from the leg portions and/or central portion of a U-shaped configuration.

As used herein, unless otherwise specified or limited, the term “S-shaped” specifies a shape that includes a central portion, with; leg portions extending in at least partially opposite directions from spatially separated portions of the central portion. In some embodiments, an “S-shaped” configuration can include leg portions extending from opposite ends of the central portion at substantially right angles to the central portion, with or without a curved or compound-angle connecting region between the leg portion and the base portion. However, other angles may be contemplated while remaining in a substantially S-shaped configuration, such as any angle between about. 45 degrees and about 135 degrees, or greater than or equal to about 45degrees and less than about 180 degrees. In some embodiments, additional protrusions or contours that do not substantially alter the overall profile of the shape can extend from the leg portions and/or central portion of an S-shaped configuration.

As used herein, unless otherwise specified or limited, the term “W-shaped” specifies a shape that includes an S-shape, as described above, with another leg portion extending from one leg portion of the S-shape in at least a partially opposite direction from the central portion of the S-shape. In some embodiments, a “W-shaped” configuration can include the other leg portion extending from the leg portion of the S-shape at a substantially right angle to the leg portion, with or without a curved or compound-angle connecting region between the leg portion and the other leg portion. However, other angles may be contemplated while remaining iii a substantially W-shaped configuration, such as any angle between about 45.degrees and about 135 degrees, or or greater than or equal to about 45 degrees and. less than about 180 degrees. In some embodiments, additional protrusions or contours that do not substantially alter the overall profile of the shape can extend from the leg portions and/or central portion of a W-shaped configuration.

Generally, electrical equipment racks include two or four posts connected between base supports and top supports, and conventional vertical cable managers attach to such racks in a side-by-side configuration. More specifically, such racks are configured to store electronic equipment, such as computers or servers, between the posts and conventional vertical cable managers are configured to be coupled beside a respective post to serve as a conduit for wires or cables of the electronic equipment Such vertical cable managers generally take the shape of a rectangular conduit and, thus, may be coupled between posts of adjacent, side-by-side racks (i.e., a respective rack may be coupled to each side of the vertical cable manager). Current vertical cable managers, however, do not allow for anything other than side-by-side configurations. Thus, if it is desirable for racks to be arranged at different angles or on different planes relative to each other, each rack must use its own vertical cable manager and adjacent racks cannot be connected or linked together.

Embodiments of the invention can address these and other issues. For example, some embodiments provide an angular vertical cable manager capable of connecting to two- or four-post electrical equipment racks in an angular fashion. More specifically, the cable manager is configured to connect to adjacent equipment racks that are angled, relative to one another (e.g., on different planes), thus generally forming an “L-shape” configuration. The cable manager can be capable of a fixed-angle relationship between the adjacent; racks or may be adjustable to provide a variable-angle relationship. Furthermore, multiple vertical cable managers may be used to form systems having, for example, “U-shaped,” “S-shaped,” “W-shaped,” or other shaped configurations of equipment racks.

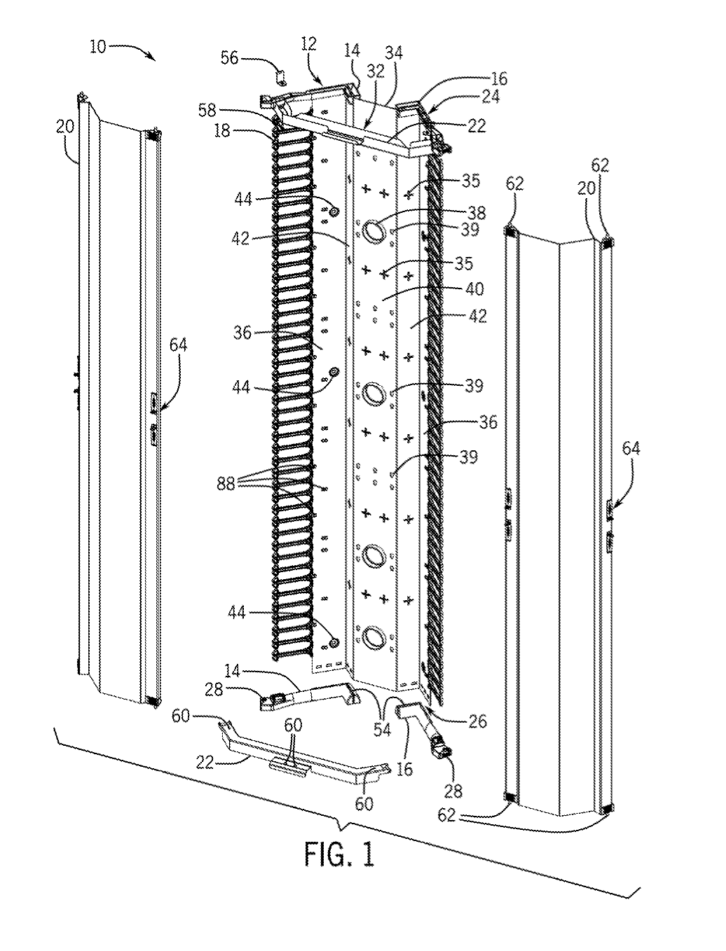

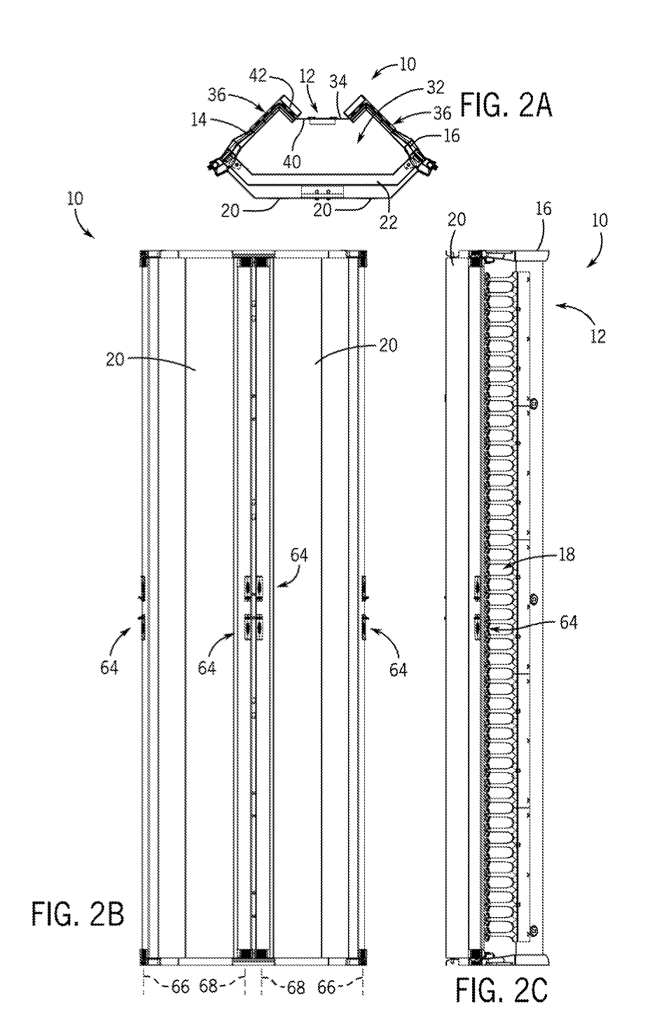

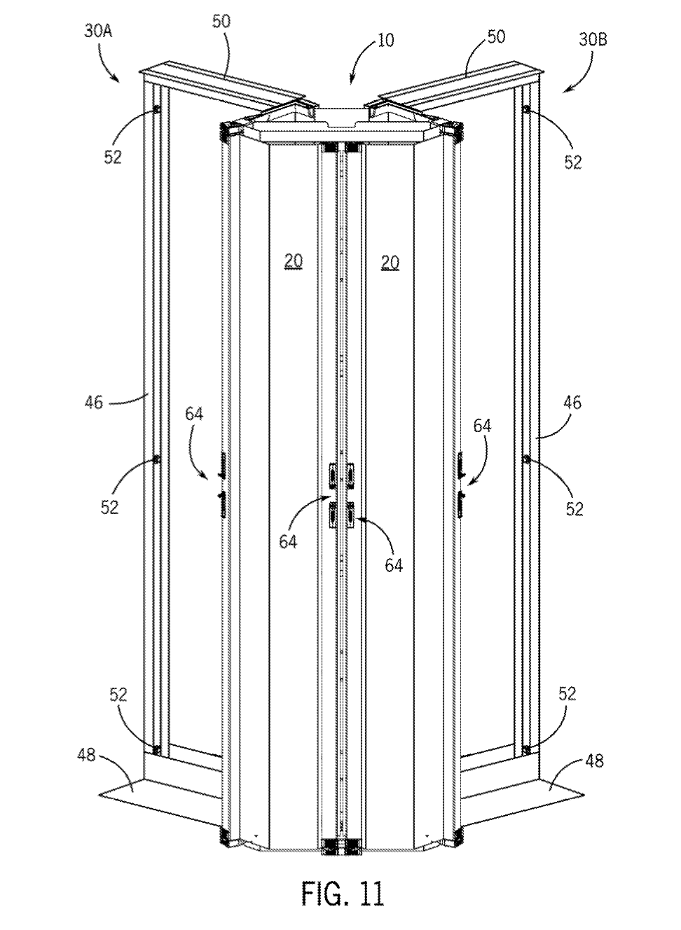

FIG. 1 illustrates an exploded view of an angular vertical cable manager 10 according to some embodiments of the invention. As shown in FIG. 1, the cable manager 10 can include a body 12, end caps 14, 16, finger arrays 18, a set of two doors 20, and cross-brace supports 22. As shown in FIGS. 2A-2C, the end caps 14, 16 can be arranged along upper and lower edges 24, 26 of the body 12, and the cross-brace supports 22 can be coupled to or otherwise engaged with outer ends 28 of the end caps 14, 16 to span across the body 12, thus defining a conduit 32 therebetween. Additionally, the doors 20 can be removably coupled to the cross-brace supports 22 and/or the end caps 14, 16 and can substantially enclose the conduit 32. As further described below, the cable manager 10 can be coupled to an electrical equipment rack 30 (as shown in FIG. 11) so that the conduit 32 can receive cables or wires linked to electronic equipment, such as computers or servers, housed within the rack 30.

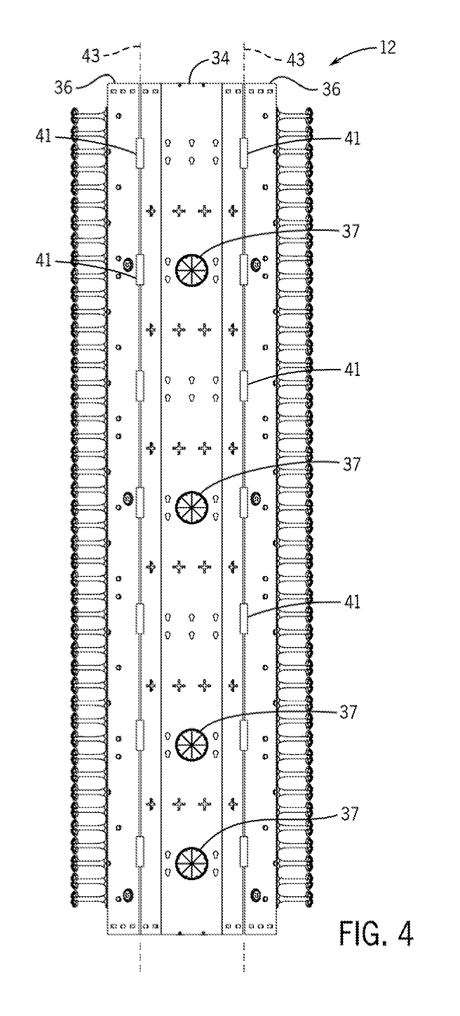

As shown in FIG. 1, the body 12 of the cable manager 10 can include a base 34 and arms 36 that extend outwardly from either side of the base 34, thus partially defining the conduit 32 (as shown in FIG. 2A). In some embodiments, the base 34 can include, for example, one or more bushings 38 sized to permit wires or cables to be routed out of the conduit 32 (e.g., to a backside of the cable manager 10) and capable of including covers 37 (shown in FIG. 4). The base 34 can also include one or more apertures 39 and/or loop features 35, for example, to facilitate attachment of additional equipment or accessories to the base 34. For example, the loop features 35 can include a pressed-in or lanced feature in the base. 34 that forms a metal loop For tying down cables (e.g., along the backside of the base 34). In some embodiments, the cross shape of the loop feature 35 can enable vertical, horizontal, or 45-degree tie-down points (e.g., by strapping, for example, Velcro through different portions of the loop feature 35).

Generally, the arms 36 can be integral with or coupled to the base 34. Additionally, in some embodiments, the base 34 can be substantially flat and the arms 36 can extend directly from the flat base 34. In other embodiments, as shown in FIGS. 1 and 2A, the base 34 can include a flat portion 40 and angled extensions 42 that extend from either side of the flat portion 40. As shown, the arms 36 can extend from these extensions 42 at an angle relative to the fiat portion 40. In some embodiments, the extensions 42 can be used to increase the size of the conduit 32. As such, as best shown in FIG. 2A, the extensions 42 can extend away from the base 34 in a backward direction, and the arms 36 can extend from the extensions 42 in a forward direction (relative to the perspective of FIG. 2A). Additionally, in some embodiments, other protrusions or contours that do not substantially alter the overall profile of the shape of the cable manager 10 can extend between the base 34 and the arms 36.

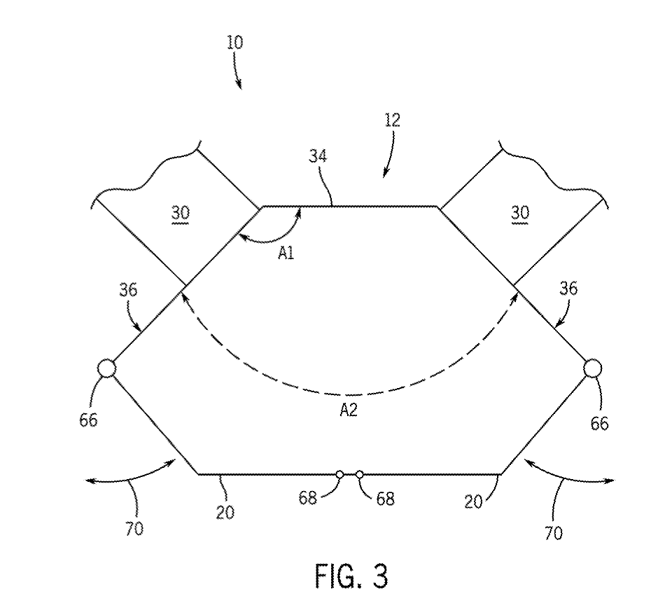

In some embodiments, each arm 36 can extend outwardly at a fixed angle relative to the base 34 such as an angle between about 45 degrees and about 180 degrees; an angle between about 90 degrees and about 180 degrees, an angle greater than about 45 degrees and less than about 180 degrees, or an angle greater than about 90 degrees and less than about 180 degrees (e.g., from about 91 degrees to about 179 degrees). In one embodiment as shown in FIGS. 2A. and 3, each arm 36 extends outward from the base 34 at about a 135-degree angle (angle A1, as shown in FIG. 3). As a result, the arms 36 are positioned at about a 90-degree angle relative to each other (angle A2, as shown in FIG. 3). Generally, the base 34 and the arms 36 can be positioned relative to each other so that the arms 36 are positioned relative to each other at an angle greater than about 0 degrees (parallel) and less than about 180 degrees. In contrast, arms of conventional cable managers are arranged parallel to one another. In some embodiments, each arm 36 extends from the base 34 at the same angle; however, in other embodiments, the arms 36 can extend from the base at different angles.

Furthermore, in some embodiments, the arms 36 can extend outwardly at variable or adjustable, angles relative to the base 34, such as via one or more pivotable connections. For example, as shown in FIG. 4, the arms 36 and the base 34 can be coupled to each other at hinged connections 41 to permit each arm 36 to be individually rotated relative to the base 34 at a desired angle (e.g., between about 45 degrees and about 180 degrees). Thus, each arm 36 can rotate about a pivot axis 43 to reach the respective desired angle.

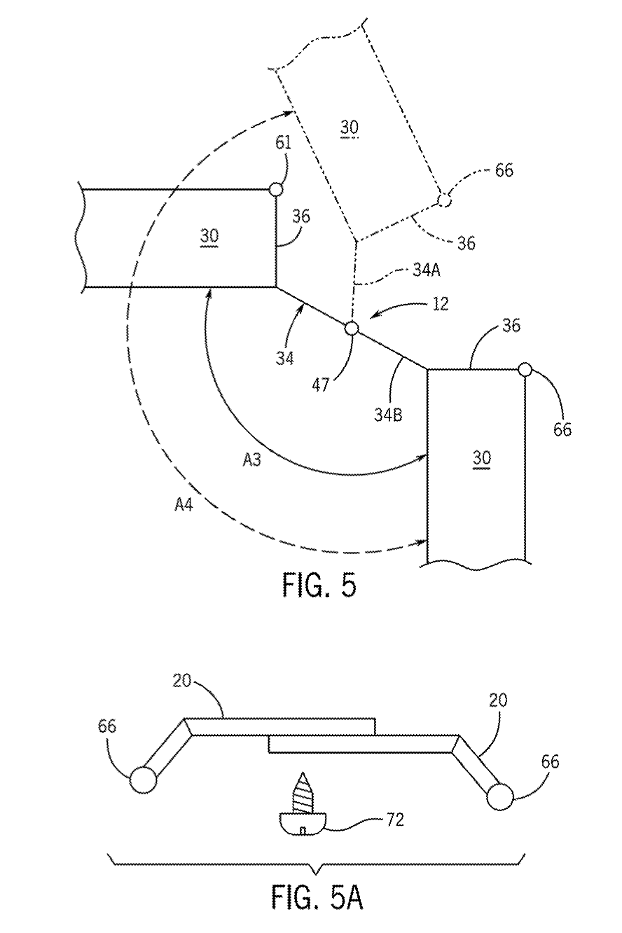

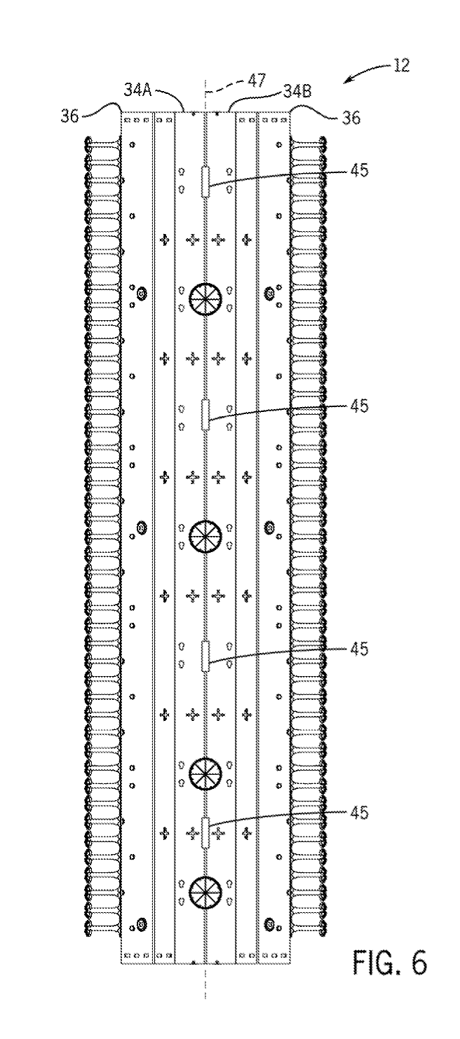

In another example, as shown in FIGS. 5 and 6, the base 34 can include two portions 34A, 34B hingedly coupled together. More specifically, the two base portions 34A, 34B can be coupled together at a hinged connection 45, forming a pivot axis 47, and each portion 34A, 34B can be integral with a respective arm 36 at a fixed angle or coupled to a respective arm 36 at a fixed or variable angle. As a result, the two base portions 34A, 34B can be rotated relative to one another about the pivot axis 47, allowing the relative angle between the arms 36 to be adjusted. In some embodiments, the hinged connections 41, 45 can be allowed to smoothly rotate and include a locking mechanism (not shown) to maintain the desired angle (or angles) between the arms 36 and the base 34. In other embodiments, the hinged connections 41, 45 can be rotated, in a smooth or stepwise fashion, to the desired angle and maintain their position at the desired angle (e.g., via friction or torque hinges). Furthermore, while multiple hinged connections 41, 45 are illustrated in FIGS. 4 and 6, some embodiments may include a single hinge that extends an entire or partial height of the base 34.

In some embodiments, as shown in FIGS. 1, 4, and 6, each arm 36 can be substantially fiat and can include one or more apertures 44 along a height of the arm 36. These apertures 44 can be used for coupling the arm 36 to a post 46 of a rack 30, as shown in FIG. 11, Furthermore, each arm 36 can include outwardly extending finger arrays 18. As shown, the finger arrays 18 can extend generally along the same plane as the respective arm 36. In use, the finger arrays 18 can receive wires or cables linked to electronic equipment (not shown) stored on the rack 30, as further described below.

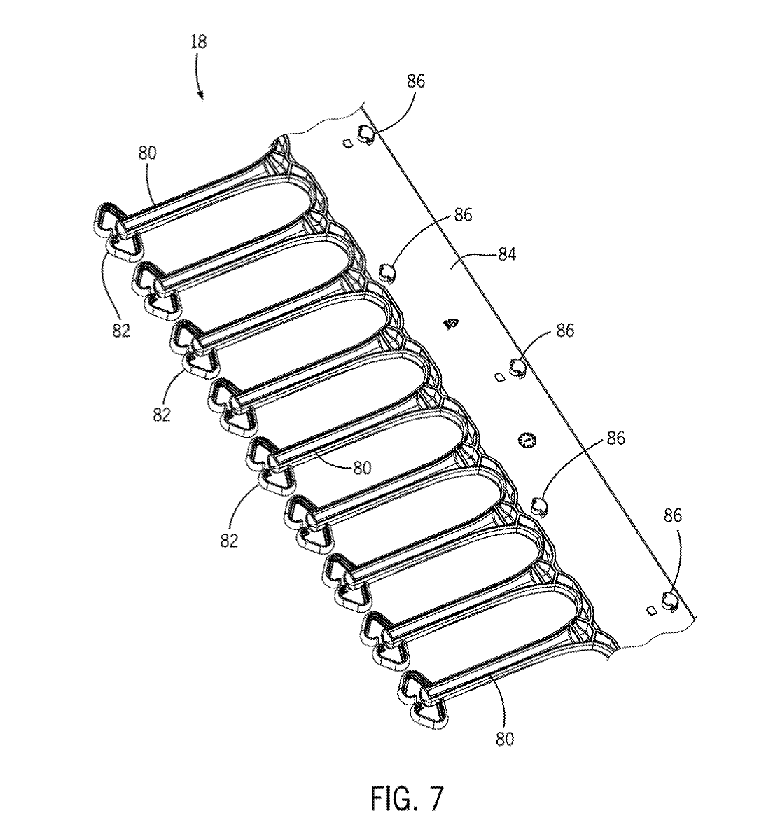

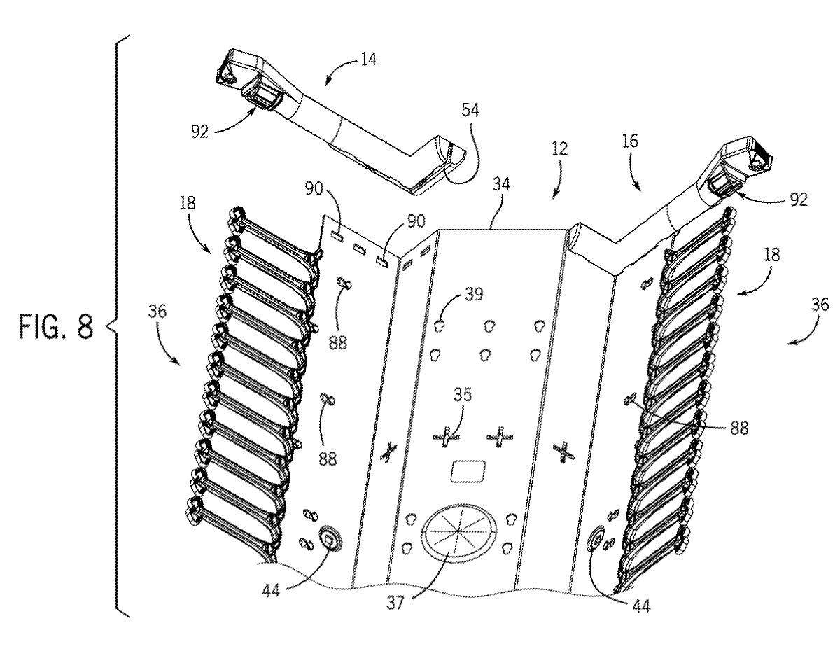

In some embodiments, the finger arrays 18 can be similar in shape and function to that described in U.S. Pat. No. 7,973,242, the entire contents of which is incorporated herein by reference. For example, as shown in FIG. 7, each finger array 18 can include a plurality of fingers 80 with arrow-shaped heads 82. The finger array 18 can also include a base 84 integral with the fingers 80 and including hooks 86 configured to be received by apertures 88 of a respective arm 36 (as shown in FIGS. 1 and 8). As a result, multiple finger arrays 18 can be arranged along a height of each arm 36 by engaging the hooks 86 into respective apertures 88. Alternatively, in some embodiments, the fingers 80 can be individually coupled to the base 84 and/or the arms 36.

In addition to the finger arrays 18, the end caps 14, 16 can be coupled to the arms 36. For example, in some embodiments, as shown in FIG. 1, the end caps 14, 16 can be positioned on upper and lower edges 24, 26 of the body 12, and can extend along the arms 36 as far as, or past, the finger arrays 18. Generally, the end caps 14, 16 can be mirror images of each other to align with a respective aim 36 and a respective angled, portion of the base 34. For example, in some embodiments, as shown in FIGS. 1 and 8, each end cap 14, 16 can include a slot 54 to receive a respective upper or lower edge 24, 26 of the arm 36. Internal flexed protrusions (not shown) can extend into the slot 54 to snap into apertures 90 of the arms 36 when the end caps 14, 16 are pressed onto the upper or lower edges 24, 26 of the arms 36. The end caps 14, 16 can also include a release mechanism 92 that forces the protrusions out of the apertures 90 when pressed, allowing the end caps 14, 16 to be decoupled from the arms 36.

In other embodiments, the end caps 14, 16 can be otherwise coupled to or engaged with the arms 36. Also, in some embodiments, the end caps 14, 16 can align only with a respective arm 36, or a single end cap can extend across both arms 36 and the base 34. Generally, the end caps 14, 16 can help provide stability to the cable manager 10 and can also act as engagement points for the cross-brace supports 22.

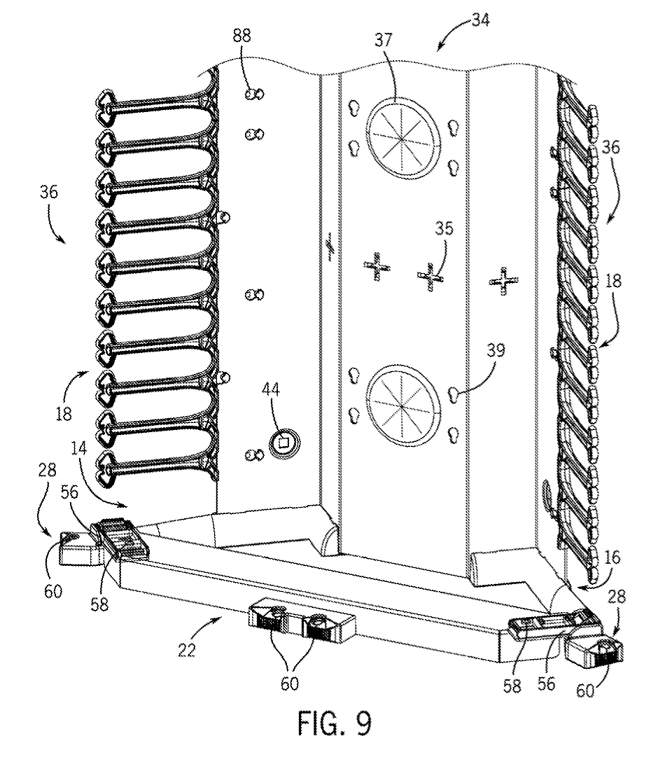

More specifically, in some embodiments, as shown in FIGS. 1 and 9, the end caps 14, 16 can extend the length of the arms 36 and past the finger arrays 18 to engage the cross-brace supports 22. For example, each cross-brace support 22 can extend from an outer end 28 of one end cap 14, 16 (that is, an end distal from the body 12) to an outer end 28 of the other end cap 14, 16. In one embodiment, the cross-brace supports 22 are coupled to respective end caps 14, 16 via one or more cross-brace clamps 56 and fasteners 58, as shown in FIGS. 1 and 9. Accordingly, the cross-brace supports 22 can help further define the conduit 32, as shown in FIG. 2A.

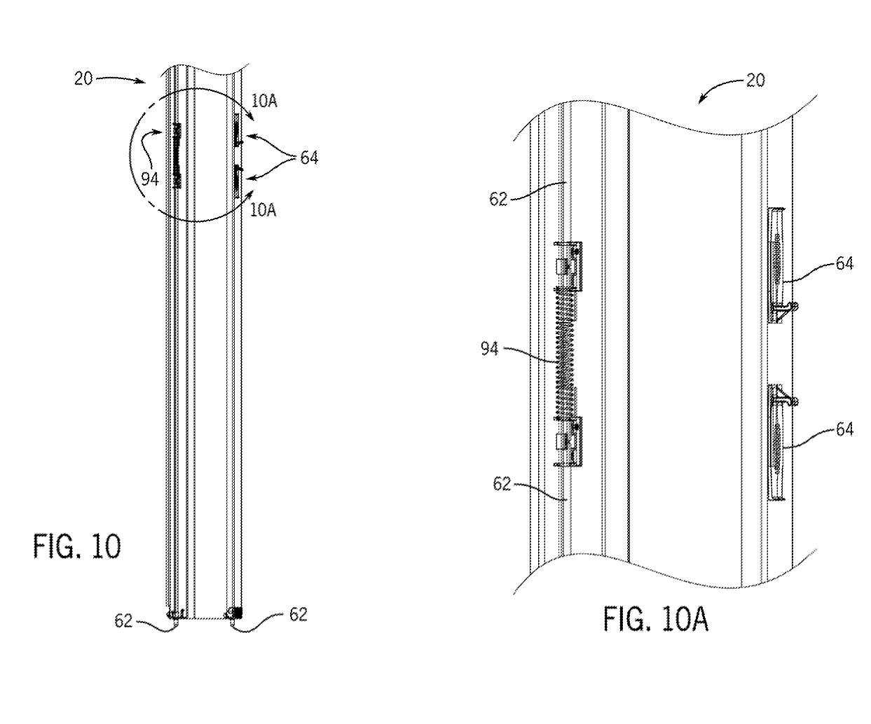

Furthermore, the doors 20 can be coupled, to the cross-brace supports 22 in order to substantially enclose the conduit 32. For example, the doors 20 can generally extend from one arm 36 to the other arm 36 to define the conduit 32 between the doors 20 and the body 12. More specifically, the doors 20 can be positioned in a side-by-side configuration to extend from one arm 36 to the other arm 36. In one embodiment, each cross-brace support 22 and/or each end cap 14, 16 can include one or more apertures 60 (as shown in FIGS. 1 and. 9) sized, to receive retractable latch rods 62 of a door 20 (shown in FIGS. 1 and 10). Each door. 20 can therefore rotate about the latch rods 62 received within the apertures 60. The doors 20 can further include latches 64 configured to retract the latch rods 62, thus allowing each door 20 to be installed, removed, opened, or closed.

In some embodiments, all apertures 60 can be located on the cross-brace supports 22, while in other embodiments, as shown in FIG. 9, each cross-brace support 22 can include two apertures 60 (e.g., “inner” apertures 60) and each, end cap 14, 16 can include an aperture 60 (e.g., “outer” apertures 60). Furthermore, because the doors 20 engage the cross-brace supports 22 and/or the end caps 14, 16, they do not need to engage the arms 36 or the finger arrays 18.

As shown in FIGS. 1-2C and 10, each door 20 can include a set of latch rods 62, and respective latches 64, on both sides of the door 20, and the cross-brace supports 22 and/or end caps 14, 16 can include four apertures 60 to support both sets of latch rods 62 of the two doors 20. As a result, each door 20 can be configured to rotate about two separate axes (e.g., about an “outer” latch rod axis 66 or an “inner” latch rod axis 68, as shown in FIGS. 2C and 3). Accordingly, each of the two doors 20 can be individually pivoted relative to a respective arm 36. For example, the two doors 20 can be pivoted to open away from each other (e.g., both rotated about their outer latch axis 66, as shown by arrows 70 in FIG. 3), or toward each other (e.g., both rotated about their inner latch axis 68).

In another example, one door 20 can be-individually rotated about its outer latch axis 66 while the other door 20 can be rotated about its inner latch axis 68. By providing two doors 20 with multiple axes of rotation, the cable manager 10 provides easy access to the conduit 32. Additionally, by providing two doors 20, an overall footprint of the cable manager 10 can be minimal, for example, compared to a cable manager with a single door enclosing the conduit 32 (which would require a larger footprint in front of the cable manager to accommodate rotation of the larger door). However, in some embodiments, the cable manager 10 can include a single door 20. For example, the single door 20 can be latched into the outer apertures 60 of the end caps 14, 16 (or cross-brace supports 22) and be configured to pivot about either outer latch axis 66.

Generally, each door 20 can be considered closed when it is aligned with the cross-brace supports 22 and all latch rods 62 are received within apertures 60 of the cross-brace supports 22 and/or the end caps 14, 16. The door 20 can be considered opened when only a single set of latch rods 62 is received within respective apertures 60, allowing the door 20 to rotate about that single set of latch rods 62, and the door 20 can be considered removed when neither latch rod 62 is received within a respective aperture 60.

In embodiments that include a variable-angle body 12, such as that shown in FIG. 5, the doors 20 can each include a single outer latch rod set 62. At the cable manager's widest angle, inside edges of the doors 20 may abut each other or overlap,, as shown in FIG. 5A, to enclose the conduit 32. A fastener 72 or other suitable connector may be used maintain the doors 20 in the closed position (e.g., by coupling the doors 20 together). At narrower angles, the doors 20 may farther overlap and the same or a different fastener maybe used to maintain the doors 20 in the closed position. For example, the doors 20 can include multiple apertures (not shown) spaced apart in a line along a width of each door 20 so that respective apertures can receive the fastener 72 at different levels of door overlap.

In some embodiments, as shown in FIGS. 10 and 10A, the latch rods 62 can run a length along an inside of the door 20 and can be biased away from the door 20 by one or more springs 94. For example, each set of latch rods 62 can include an upper latch rod 62 and a lower latch rod 62, where the spring 94 biases both the upper and lower latch rods 62 outward, thus allowing the latch rods 62 to sit within the apertures 60 of the cross-brace supports 22. The latches 64, positioned on the outside of the door 20, can be in communication with the spring 94 so that, when the latches 64 are engaged (e.g., pressed toward each other), the spring 94 is compressed and the latch rods 62 are retracted inward. In some embodiments, each door 20 can include individual latches 64 for each latch rod 62 (that is, for each upper latch rod 62 and each lower latch rod 62), as shown in FIGS. 1, 2B, 10, and 10A, or each door 20 can include a single latch 64 or other suitable component, configured to control a set of latch rods 62 (that is, both an upper and a lower latch rod 62). Furthermore, some embodiments can include rotatable latches 64 configured to compress the spring 94 for retracting one or both latch rods 62.

As described above, the cable manager 10 can be coupled to electronic equipment racks 30 in an angular fashion to form an angular cable management system. More specifically, as shown in FIG. 11, an example rack 30 can include at least two vertical posts 46 extending between a base support 48 and a top support 50. Each post 46 can include matching apertures 52 that align with the apertures 44 on the arms 36 of the cable manager 10. Thus, an arm 36 of the cable manager 10 can be arranged against a post 46 so that the respective apertures 44, 52 are aligned, and fasteners (not shown) can be used to couple the components together. As a result, a piece of electronic equipment can be stored between the vertical posts 46 at a desired height along the rack 30, and wires or cables linked to such equipment can be routed Through an adjacent linger array 18 of the cable manager 10 and into the conduit 32. It should be noted that, while two-post racks 30 are shown and described herein, it is contemplated within the scope of the disclosure for the cable managers 10 to accommodate four-post racks or other types of racks, frames, or cabinets.

As shown in FIG; 11, each arm 36 of the cable manager 10 can be coupled to a respective vertical post 46 of a rack 30, permitting the cable manager 10 to accommodate two racks 30. As a result, each rack 30 can extend generally perpendicular from the arm 36, forming a cable management system having an “L-shaped” configuration. For example, a first rack 30A can form a first leg of the L-shaped configuration, and a second rack 30B can form a second leg of the L-shaped configuration, substantially perpendicular from the first leg. Accordingly, unlike conventional cable managers, which only connect to racks 30 in side-by-side configurations (e.g., forming a line), the cable manager 10 is capable of connecting to racks 30 in an angled configuration. In other words, while conventional cable managers only allow for adjacent racks 30 to be positioned relative to each other at a 180-degree angle, the cable manager 10 can allow adjacent racks 30 to be positioned relative to each other at angles less than 180 degrees, such as about 90 degrees (as shown by angle A3 in FIG. 5), 120 degrees (as shown by angle A4 in FIG. 5), or other angles not specifically shown or described herein. As such, the adjacent racks 30 are positioned along different, non-parallel planes when coupled to the cable manager 10. Furthermore, as described above, the cable manager 10 can allow adjacent racks 30 to be positioned at fixed angles relative to each other, or can permit adjustable, variable angled configurations.

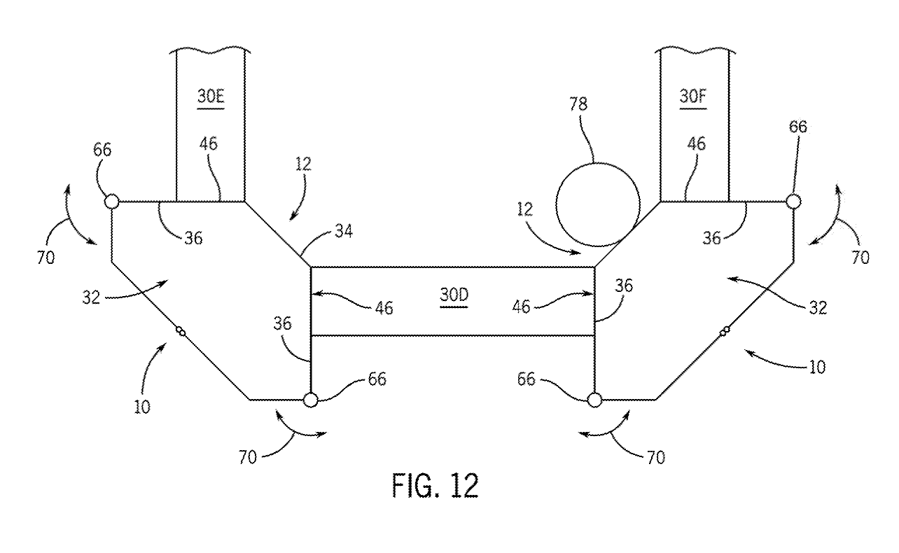

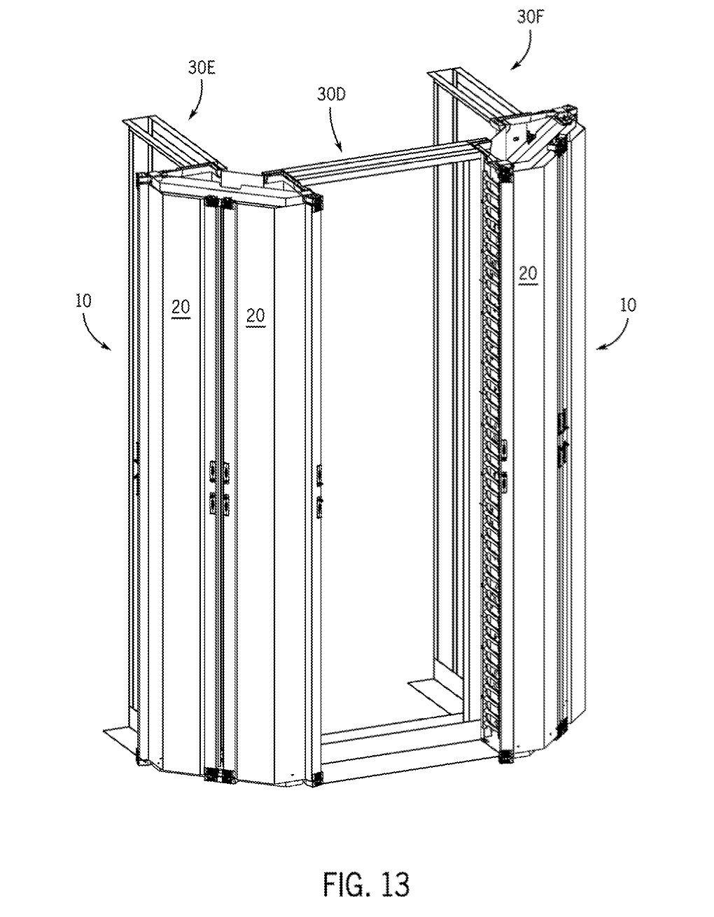

Accordingly, the cable manager 10 can be coupled to adjacent racks 30 in a more compact footprint compared to conventional in-line configurations. For example, in some applications, the L-shaped configuration shown in FIG. 11 can permit racks 30 to wrap around a corner of a wall or fit within a narrower footprint compared to a conventional in-line configuration. Furthermore, in some embodiments, systems of multiple cable managers 10 can be used to couple together multiple racks 30 in various configurations. For example, FIGS. 12-14 illustrate a cable management system having a “U-shaped” configuration, formed by two cable, managers 10 and three racks 30. In the U-shaped configuration, the cable managers 10 can be configured so that the three adjacent racks 30 are positioned at 90-degree angles relative to one another. In other words, two L-shaped configurations can share a common central rack 30D, where the two outer racks 30E, 30F generally extend from the central rack 30D in the same direction to form a U-shape. In some embodiments, the cable managers 10 can be configured so that, the adjacent racks 30 are positioned relative to one another at angles other than 90 degrees while still forming a general U-shape.

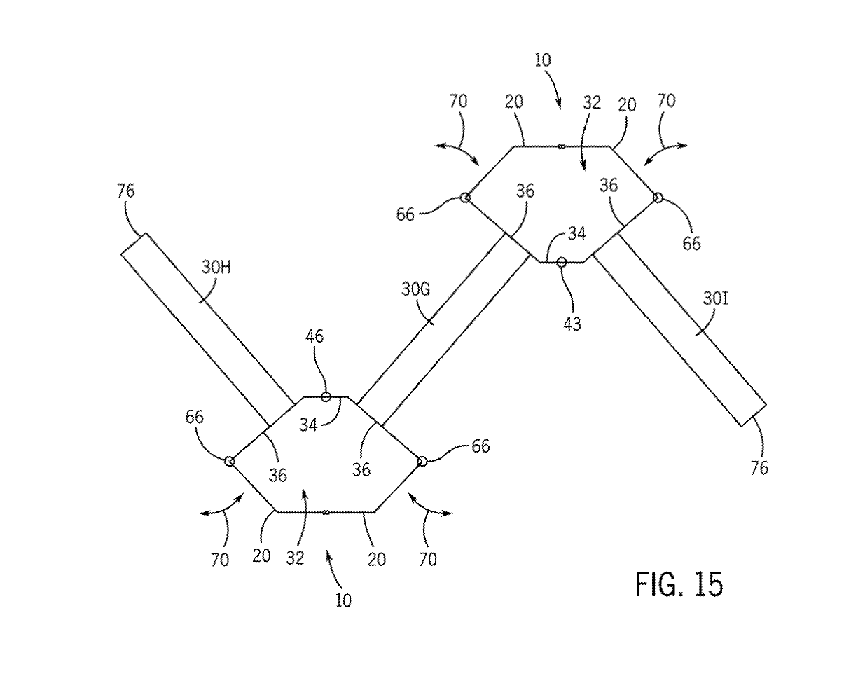

According to another example, FIG. 15 illustrates a cable management system having an “S-shaped” configuration, formed by two cable managers 10 and three racks 30. In this example, two L-shaped configurations can share a common central rack 30G, where the two outer racks 30H, 30I generally extend from the central rack 30 in opposite directions to form an S-shape (e.g., in contrast to the U-shaped configuration, where the outer racks 30E, 30F generally extend in the same direction).

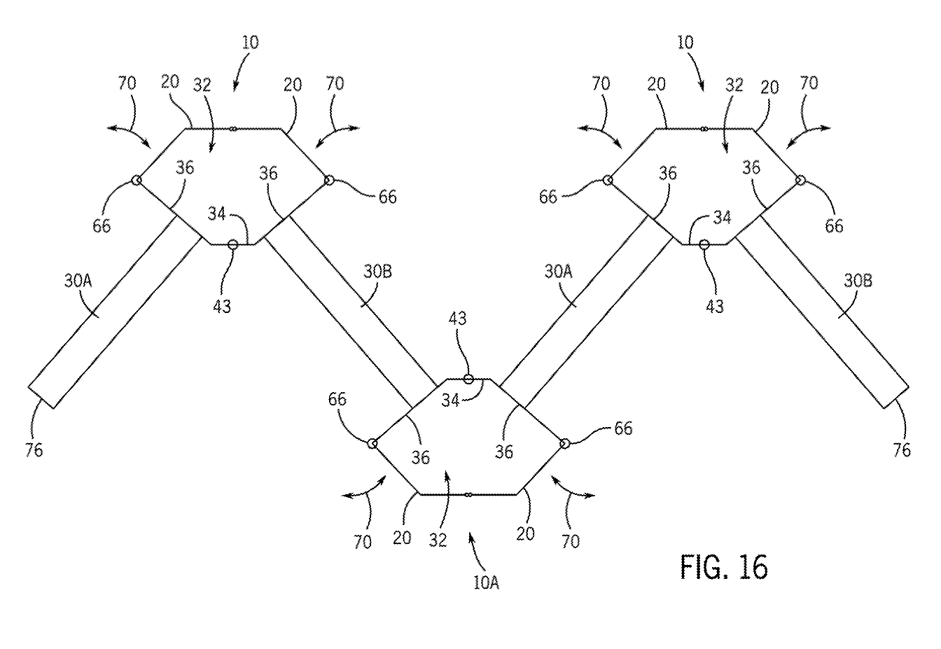

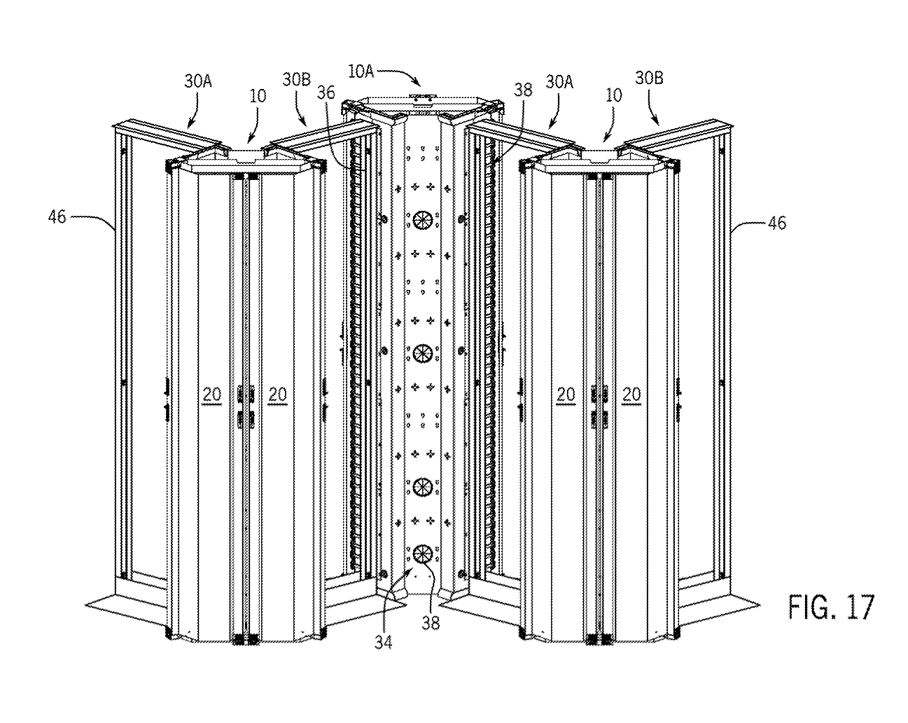

In yet another example, FIGS. 16-17 illustrate a cable management system having a “W-shaped” configuration, formed by three cable managers 10 and four racks 30. In this example, two separate L-shaped configurations are connected by a third, central cable manager 10A to form a W-shape. Alternatively, the W-shaped configuration can be considered an S-shaped configuration with an additional cable manager 10 and rack 30. Additionally, in some embodiments, a cable management system can incorporate a combination of one or more of the above configurations.

As shown in the U-shaped configuration of FIG. 1.4, standard cable managers 74 can be coupled to free ends 76 of the racks 30. For example, a standard cable manager 74 can include a base 96, parallel arms 98 that each extend from the base 96 in a perpendicular manner, and a door 100. Furthermore, standard cable managers 74 can be coupled between the present cable managers 10 in airy of the above-described configurations. For example, in one embodiment, a system of multiple racks 30 can be coupled in-line using standard cable managers 74, and the cable manager 10 can be used at a free end 76 of one rack 30 to form a turn, thus forming a larger L-shaped configuration (e.g., resulting one or both legs of the L-shaped configuration being lengthened). This concept can be similarly applied to the above-described U-shaped, S-shaped, and W-shaped systems or other configurations.

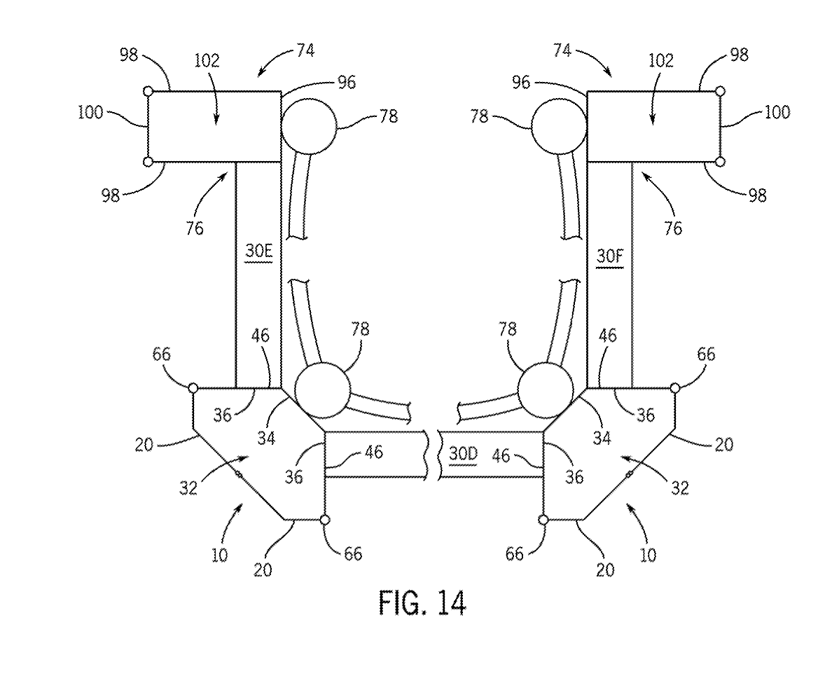

As shown in FIG. 14, the conduit 32 of the cable manager 10 is substantially larger than a conduit 102 of the standard cable manager 74. This is generally due to the angled relationship between the base 34 and the arms 36 of the cable manager 10. As a result, the cable manager 10 is capable of accommodating large amounts of cables and increased cable density compared to standard cable managers 74. Furthermore, in some embodiments, additional equipment, such as patch panels, cable loops, cable racks, or other suitable equipment, can be coupled to an inner side or outer side of the base 34 to further assist with cable management. For example, FIGS. 12 and 14 illustrate cable loops 78 coupled to outer sides of the bases 34 of respective cable managers 10. Herein, the inner side of the base 34 may be considered the side facing the conduit 32, while the outer side of the base 34 may be considered the side outside of the conduit 32.

Consistent with the discussion above, embodiments of the disclosure provide an angular or adjustable angular cable manager 10 for use with electronic equipment racks 30. The cable managers 10 described herein are capable of coupling together multiple racks 30 in various configurations, such as L-shaped, S-shaped, U-shaped, W-shaped, or other shaped configurations to form cable management systems. These configurations can include smaller footprints with reduced overall lengths compared to conventional in-line configurations of standard cable managers, and are capable of accommodating larger amounts of cables in higher densities compared to standard cable managers.

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown, herein but is to be accorded the widest scope consistent with the principles and novel features disclosed herein. Furthermore, the term “about” means a range of plus or minus 20% with respect to the specified value, more preferably plus or minus 10%, even more preferably plus or minus 5%, most preferably plus or minus 2%.

The previous description of the disclosed embodiments is provided to enable any person skilled in the art to make or use the invention. Various modifications to these embodiments will be readily apparent to those skilled in the art, and the generic principles defused herein may be applied to other embodiments without departing from the spirit or scope of the invention. Thus, the invention is not intended to be limited to the embodiments shown herein but is to be accorded the widest scope consistent with the principles and novel features disclosed herein.

1. A cable manager configured to be coupled to at least one electronic equipment rack, the cable manager comprising:
a base;
a first arm extending from one side of the base at a first angle that is greater than about 90 degrees and less than about 180 degrees, the first arm configured to be coupled to a first electronic equipment rack; and
a second arm extending from another side of the base at a second angle that is greater than about 90 degrees and less than about 180 degrees, the second aim configured to be coupled to a second electronic equipment rack.

2. The cable manager of claim 1, wherein the base include two base portions configured to pivot relative to each other to vary an angle between the first arm and the second arm.

3. The cable manager of claim L wherein at least one of the first arm and the second arm is configured to pivot relative to the base to vary an angle between the first arm and the second arm.

4. The cable manager of claim 3, wherein at least one of the first arm and the second arm is coupled to the base by a hinged connection.

5. The cable manager of claim 1, wherein the base, the first arm, and the second arm form a body, and further comprising a door extending from the first arm to the second arm so that a conduit is formed between the door and the body.

6. The cable manager of claim 5, wherein the door includes a first door and a second door arranged side-by-side.

7. The cable manager of claim wherein the first door is pivotable relative to the first arm and the second door is pivotable relative to the second arm.

8. The cable manager of claim 7, wherein each of the first door and the second door is pivotable about two separate axes.

9. The cable manager of claim 6 and further comprising a first end cap coupled to an edge; of the first arm and a second end cap coupled to an edge of the second arm.

10. The cable manager of claim 9 and further comprising a first cross-brace support coupled to the first end cap and the second end cap and extending from the first arm to the second arm.

11. The cable manager of claim 10, wherein the first door and the second door are each coupled to one of the first cross-brace support the first end cap, and the second end cap.

12. A cable management system comprising:
an angular cable manager including a body with a base and a first arm and a second arm extending from either side of the base to partially define a conduit between the base, the first arm, and the second arm;
a first electronic equipment rack coupled to the first arm; and
a second electronic equipment rack coupled to the second arm, the second-electronic equipment rack positioned relative to the first electronic equipment rack at an angle less than about 180 degrees.

13. The cable management system of claim 12, wherein the angle is adjustable.

14. The cable management system of claim 13, wherein the angle is adjustable due to at least one of the first arm and the second arm being pivotably coupled to the base.

15. The cable management system of claim 13, wherein the angle is adjustable due to the base including a first base portion pivotably coupled to a second base portion, the first base portion being coupled to or integral with the first arm and the second base portion being coupled to or integral with the second arm.

16. The cable management system of claim 12 and further comprising a second angular cable manager coupled to the second electronic equipment rack; and a third electronic equipment rack coupled to the second angular cable manager.

17. The cable management system of claim 16, wherein the first, second and third electronic equipment racks are positioned relative to each other to form a U-shape.

18. The cable management system of claim 16, wherein the first, second, and third electronic equipment racks are positioned relative to each other to form an S-shape.

19. The cable management system of claim 16 and further comprising a third angular cable manager coupled to the third electronic equipment rack; and a fourth electronic equipment rack coupled to the third angular cable manager, wherein the first, second, third, and fourth electronic equipment racks are positioned relative to each other to form a W-shape.

20. The cable management system of claim 12, wherein the angular cable manager includes a set of doors configured to extend from the first arm to the second arm to define the conduit between the base, the first arm, the second arm, and the doors.
